(19) United States
(12) Patent Application Publication
(10) Pub. No.: US 2019/0171253 A1
(43) Pub. Date: Jun. 6, 2019

(54) INFORMATION PROCESSING DEVICE AND FIXTURE

(71) Applicant: FUJITSU CLIENT COMPUTING LIMITED, Kawasaki-shi (JP)

(72) Inventor: Noritaka HARA, Kawasaki-shi (JP)

(21) Appl. No.: 16/266,481

(22) Filed: Feb. 4, 2019

Related U.S. Application Data
(63) Continuation of application No. PCT/JP2017/037054, filed on Oct. 12, 2017.

(30) Foreign Application Priority Data
Oct. 18, 2016 (JP) 2016-204372

(51) Int. Cl. G06F 1/16; G06F 1/18; H05K 5/02

(52) U.S. Cl. CPC G06F 1/1616; G06F 1/1656; H05K 5/0217; G06F 1/18

(57) ABSTRACT

An information processing device includes: a display panel; a casing having the display panel enclosed therein; a rib provided at a predetermined interval from an edge of the casing and configured to position the display panel; and a fixture provided between the display panel and the rib. The fixture includes a flange portion extending in a direction toward the edge of the casing from the fixture and configured to block the movement of a cable wired between an edge of the casing and the rib so that the cable is prevented from deviating from the edge of the casing and the rib.

This application is a continuation application based on a PCT International Application No. PCT/JP2017/037054, filed on Oct. 12, 2017, whose priority is claimed on Japanese Patent Application No. 2016-204372, filed on Oct. 18, 2016. The entire content of both the above PCT International Application and the Japanese Application are incorporated herein by reference.

### FIELD OF THE INVENTION

The present invention relates to an information processing device including a display panel and a fixture configured to fix the display panel.

### DESCRIPTION OF RELATED ART

Portability of information processing devices such as a notebook type personal computer (hereinafter referred to as a “notebook computer”) has been emphasized and miniaturization and thinning of information processing devices is progressing. For example, in order to reduce the thickness of an information processing device, a cable or the like of a wireless antenna formerly disposed on a rear surface of a display panel such as a liquid crystal display (LCD) may be configured to extend to a main body side along the inside of an edge of a display portion. In addition, a display portion may also be narrowed along with a decrease in width of an information processing device and a display panel may be configured to be installed at the vicinity of an edge of a display portion. For this reason, cables are required to be reliably fixed within a limited space such that they do not protrude. Japanese Unexamined Patent Application, First Publication No. 2013-76938 describes a notebook computer in which a cable of an antenna or the like is disposed in a casing frame surrounding an outer circumference of a display panel.

### SUMMARY OF THE INVENTION

According to an aspect, an information processing device includes: a display panel; a casing having the display panel enclosed therein; a rib provided at a predetermined interval from an edge of the casing and configured to position the display panel; and a fixture provided between the display panel and the rib, wherein the fixture includes a flange portion extending in a direction toward the edge of the casing from the fixture and configured to block movement of a cable wired between an edge of the casing and the rib.

According to another aspect, a fixture which is installed between a display panel and a rib in a casing and positions the display panel includes: a wall portion which is in contact with a part of a side surface of the display panel on one surface thereof and is in contact with the rib on the other surface opposite to the one surface; a receiving portion extending from one end portion of the wall portion to receive a rear surface of the display panel; and a flange portion extending from the other end portion of the wall portion toward a side opposite to the receiving portion.

### BRIEF DESCRIPTION OF THE DRAWINGS

FIG. 1 is a perspective view showing an information processing device in the disclosure.

FIG. 2 is a perspective view of a display section in the information processing device in the disclosure with an upper lid which has been removed.

FIG. 3 is an enlarged partial perspective view of a portion A in FIG. 2.

FIG. 4 is an exploded perspective view of a portion shown in FIG. 3.

FIG. 5A is an exploded perspective view of a display section in an information processing device in a comparative technique with an upper lid which has been removed.

FIG. 5B is a perspective view showing a structure for positioning of the display panel.

FIG. 6 is a cross-sectional view taken along line VI-VI in FIG. 3.

FIG. 7A is a perspective view of a fixture used in the information processing device in the disclosure when viewed obliquely from above.

FIG. 7B is a perspective view of the fixture when viewed obliquely from below.

FIG. 8A is a diagram showing another example of the fixture, which is a perspective view of the fixture when viewed obliquely from above.

FIG. 8B is a diagram showing yet another example of the fixture, which is a perspective view of the fixture when viewed obliquely from below.

FIG. 9 is a partial perspective view of the casing in the information processing device, which is a diagram showing a shape of a rib.

FIG. 10 is a cross-sectional view showing another example of the fixture.

### BRIEF DESCRIPTION OF THE INVENTION

Embodiments of the present invention will be described in detail below with reference to specific examples using the accompanying drawings. Furthermore, in the following examples, the same or similar constituent elements are denoted by the same reference numerals and the sizes thereof may be appropriately changed in the drawings in order to facilitate understanding.

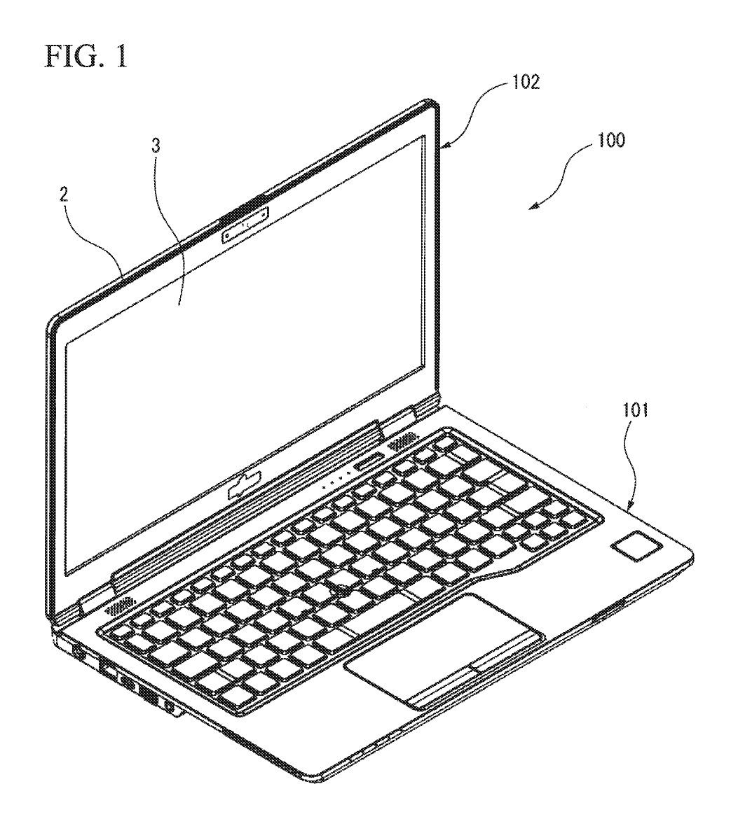

FIG. 1 is a perspective view showing a notebook computer 100 which is an example of an information processing device in an embodiment. The notebook computer 100 includes a main body device 101 and a display portion 102 which is opened and closed via a hinge at a rear end portion of the main body device 101. FIG. 1 shows a state in which the display portion 102 is open.

A circuit board having electronic parts such as a CPU (central processing unit) (not shown) installed therein is accommodated inside the main body device 101. An input apparatus such as a keyboard and a touch panel is provided above an upper surface of the main body device 101. The display portion 102 includes a display panel 3 which is a liquid crystal display (LCD) and a casing 2 having the display panel 3 accommodated therein.

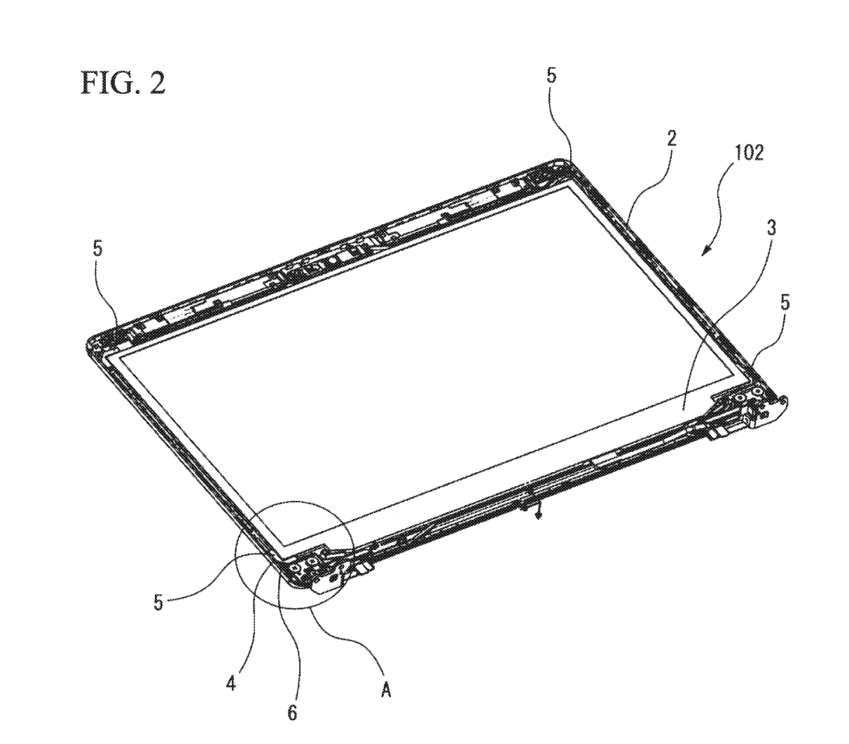

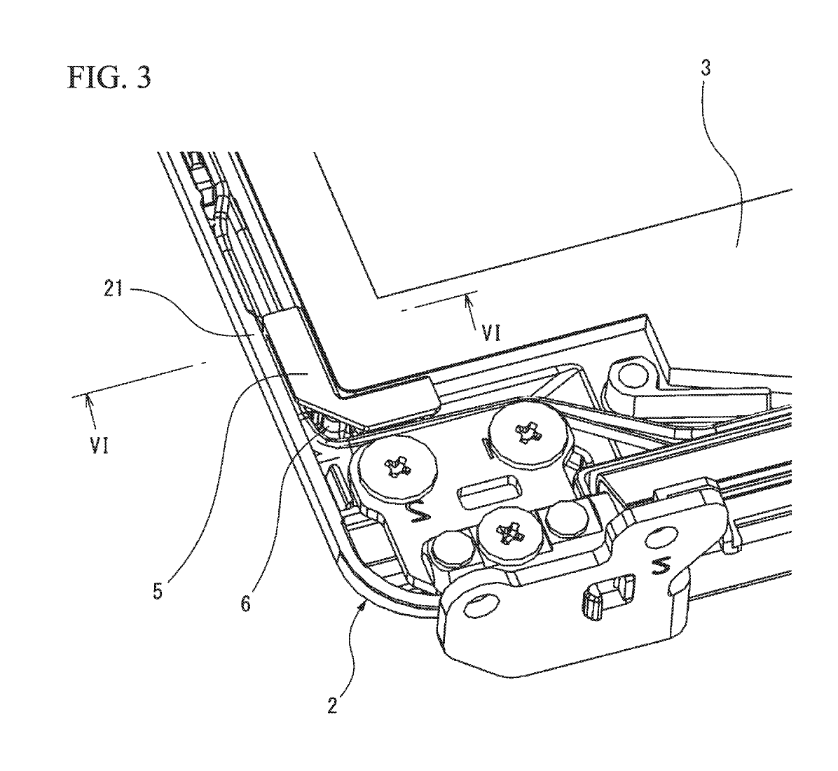

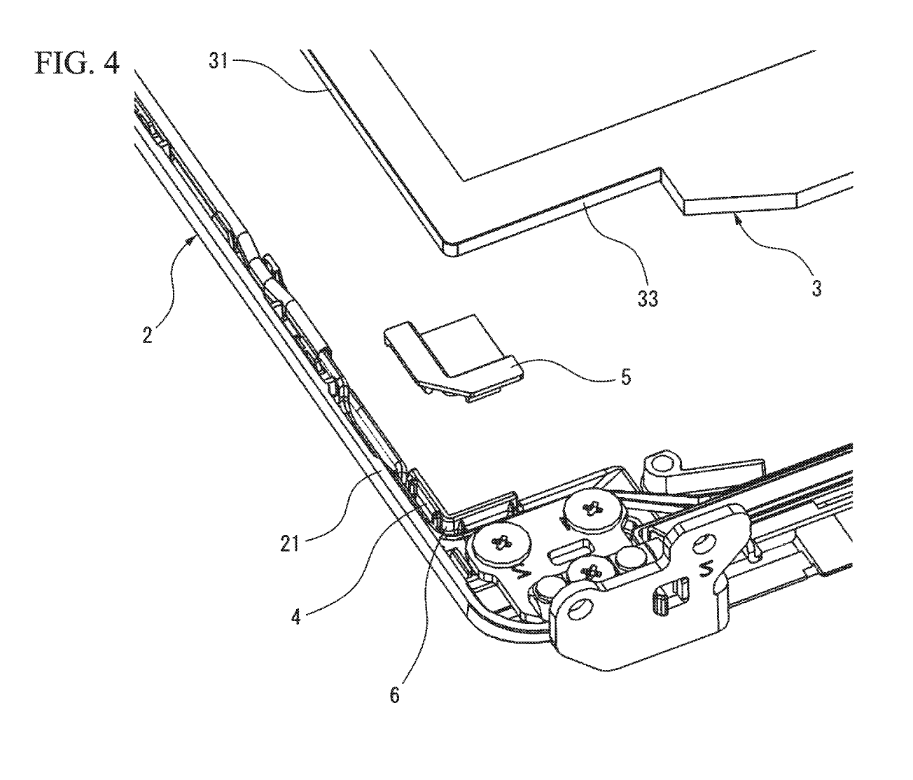

FIG. 2 is a perspective view showing the inside of the display portion 102 in the notebook computer 100 and is a diagram showing a state in which an upper lid (not shown) of the display portion 102 has been removed. FIG. 3 is an enlarged partial perspective view of a portion A in FIG. 2. As shown in FIG. 2, the display panel 3 is formed in a rectangular shape as a whole. A rib 4 (refer to FIG. 4) disposed at a predetermined interval from an edge portion 21 (refer to FIG. 3) of the casing 2 and configured to position the display panel 3 is formed in the casing 2. The display panel 3 is fitted between four fixtures 5 provided between the display panel 3 and the ribs 4 at its four corners and is positioned in the casing 2. A cable 6 configured to connect the display panel, an antenna, a camera, and the like to the main body device 101 is wired between the edge portion 21 of the casing 2 and the ribs 4 around the display panel 3. Since functions and structures of the fixtures 5 disposed at the four corners of the display panel 3 are the same, the fixtures 5 shown in a portion A in FIG. 2 will be described later.

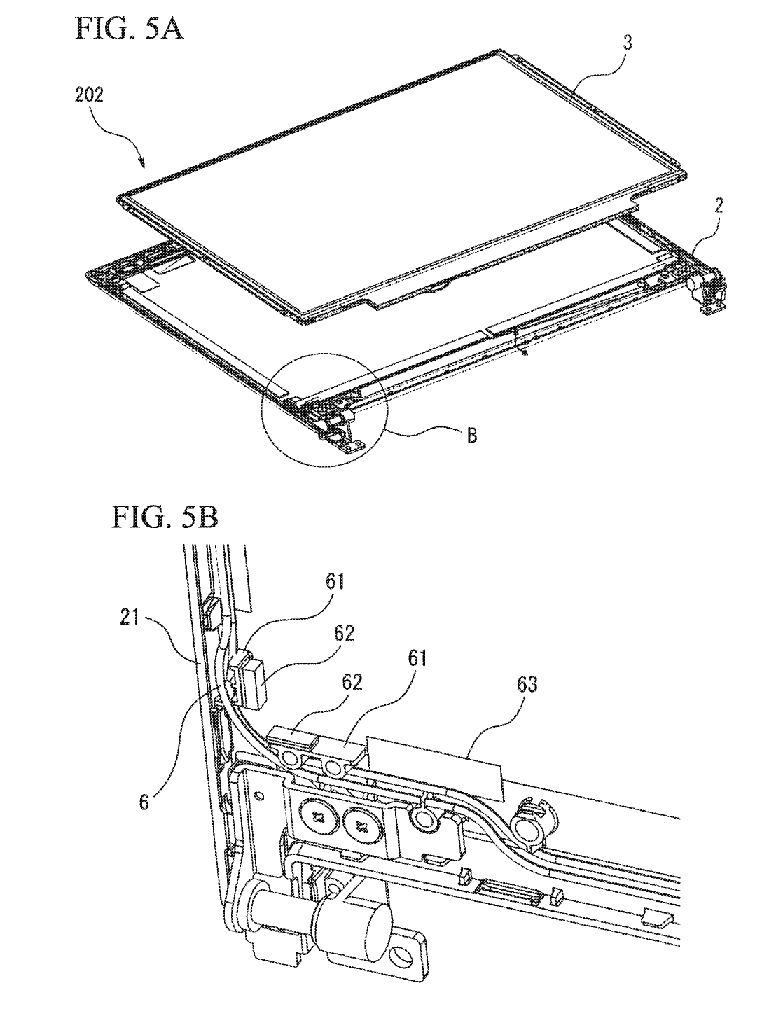

Here, a notebook computer which is an information processing device in a comparative technique will be described with reference to FIG. 5A and FIG. 5B. FIG. 5A is an exploded perspective view showing a structure of a display portion 202 in the notebook computer in the comparative technique and FIG. 5B is an enlarged diagram of a portion B in FIG. 5A, which is a partial perspective view showing a structure of positioning of the display panel 3.

The display panel 3 in the comparative technique is enclosed in the casing 2 in the display portion 202. As shown in FIG. 5B, the display panel 3 has its four corners positioned by sponges 62 adhered to ribs 61 provided in the display portion 202. Moreover, in the notebook computer in the comparative technique, the cable 6 extends between the ribs 61 and the edge portion 21 of the casing 2 along the circumference of the display panel 3. Since the cable 6 is bent along the ribs 61, the cable 6 tends to ride over the ribs 61 due to a bending reaction force of the cable 6 itself and the lifting of the cable 6 increases particularly in the vicinity of the four corners of the display panel 3. In the notebook computer in the comparative technique, this lifting up is prevented by providing double-sided tape 63 on sides of the ribs 61 at the four corners of the display panel 3 and adhering the cable 6 onto the double-sided tape 63 in some cases. Here, it may be difficult to adhere the cable 6 onto the double-sided tape 63 depending on a surface treatment performed on an outer layer of the cable 6 such as a coaxial cable or the like. Furthermore, when assembling the display portion 202, very detailed work in which the sponges 62 are adhered to the ribs 61 of the display portion 202 or the double-sided tape 63 is adhered to the casing to fix the cable 6 is required.

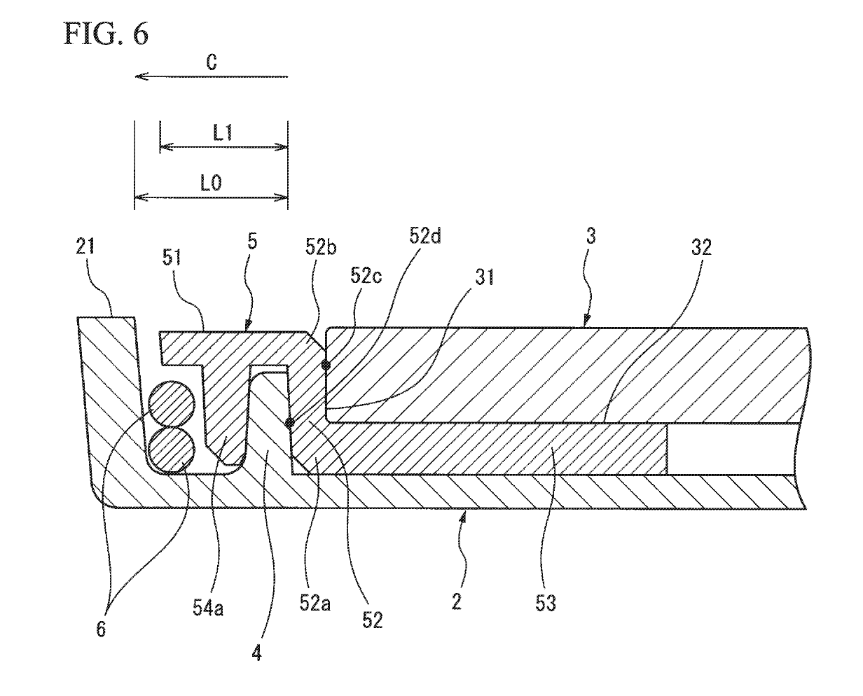

On the other hand, as shown in FIG. 6, the notebook computer 100 in the embodiment includes a flange portion 51 provided to extend from the fixtures 5 in a direction toward an edge of the casing 2 (arrow C), that is, the edge portion 21 of the casing 2, when the display panel 3 is positioned in the casing 2. For this reason, movement of the cable 6 wired between the ribs 4 and the edge portion 21 of the casing 2 is blocked by the flange portion 51. Thus, lifting up of the cable 6 is prevented. For example the cable 6 protruding from the ribs 4 and the edge portion 21 of the casing 2 is prevented when assembling the display portion 102. Since the lifting up of the cable 6 is prevented, the cable 6 is not sandwiched between the casing 2 and the upper lid when attaching the upper lid.

Each of the fixtures 5 includes a wall portion 52 and the wall portion 52 is in contact with a part of a side surface 31 of the display panel 3 on one surface 52c and is in contact with the rib 4 on the other surface 52d opposite to the one surface 52c. Furthermore, the fixture 5 has a receiving portion 53 extending from one end portion 52a of the wall portion 52 to receive a rear surface 32 of the display panel 3. As shown in FIG. 6, the flange portion 51 in the fixture 5 extends from the other end portion 52b of the wall portion 52 toward a side opposite to the receiving portion 53. The fixture 5 further includes a protruding portion 54a protruding from the flange portion 51 toward the rib 4 and configured to sandwich the rib 4 in cooperation with the wall portion 52.

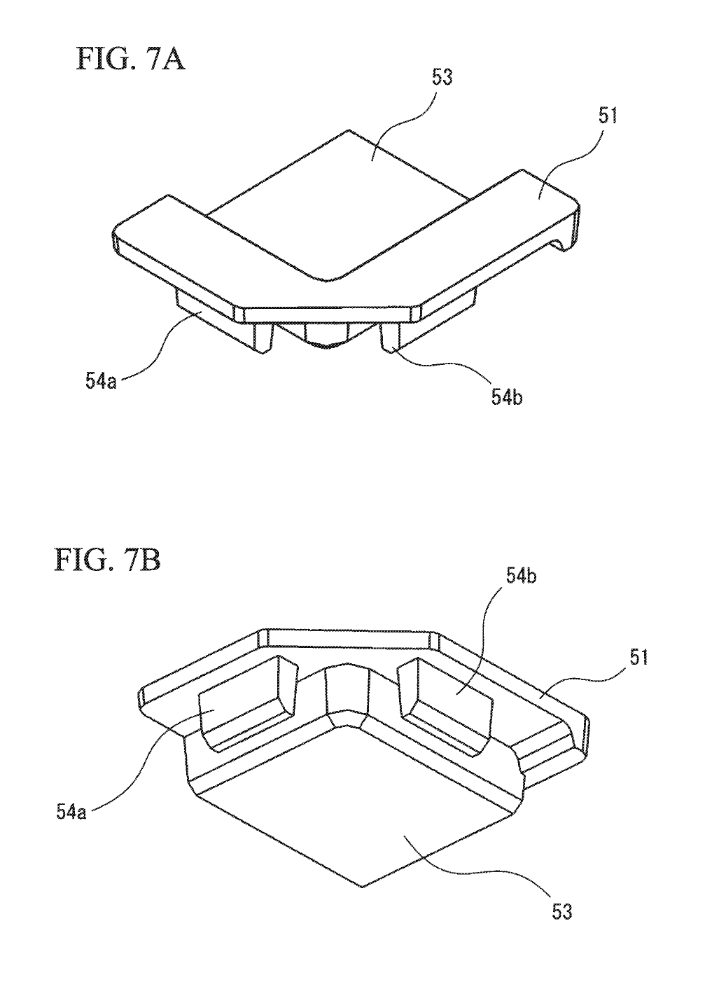

FIG. 6 shows the flange portion 51 and the wall portion 52 which is in contact with a part of the side surface 31 in a short side direction of the display panel 3. As shown in FIG. 7A and FIG. 7B, the wall portion 52 which is in contact with the side surface 33 (refer to FIG. 4) in a long side direction of the display panel 3 are formed on the fixture 5 and the protruding portion 54b (hereinafter, the protruding portions 54a and 54b are collectively referred to as a protruding portion 54 in some cases).

When manufacturing the notebook computer 100, a manufacturer causes the cable 6 to extend along a groove between the edge portion 21 of the casing 2 and the rib 4. After that, the manufacturer installs the fixture 5 so that the rib 4 is inserted between the protruding portion 54 and the wall portion 52, that is, the rib 4 is sandwiched between the protruding portion 54 and the wall portion 52. It is possible for the manufacturer to easily fix the fixture 5 to the casing 2 by causing the rib 4 to be sandwiched between the protruding portion 54 and the wall portion 52.

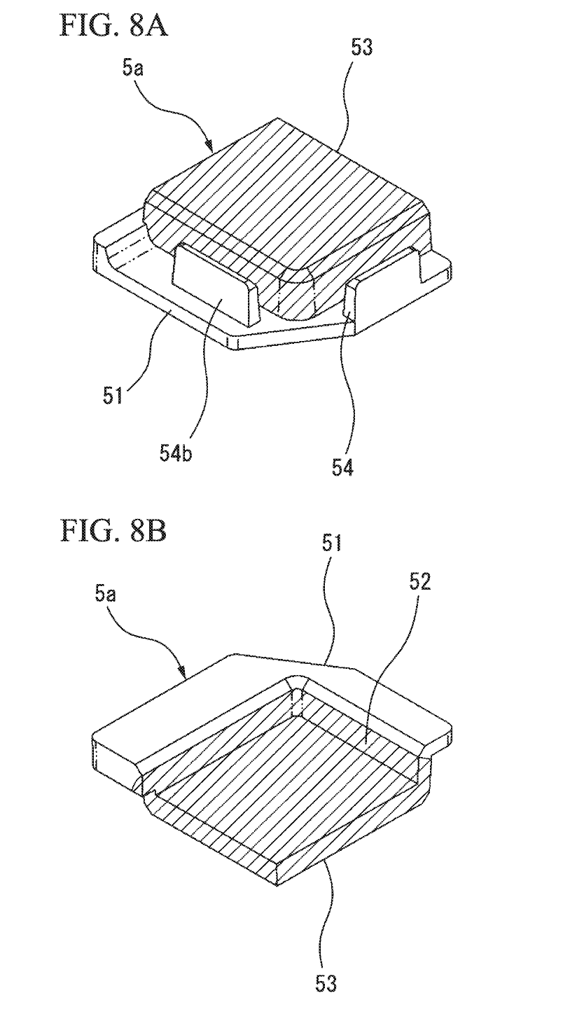

The fixture 5 in the embodiment is a molded article made of rubber. Furthermore, the fixture 5 may be formed of a resin. As shown in FIG. 8A and FIG. 8B, the fixture 5a may be formed through two color molding in which one portion at which the fixtures 5 and the display panel 3 are in contact with each other, specifically hatched portions in FIG. 8A and FIG. 8B, is made of rubber and the other portions are made of a resin.

Although a plurality of sponges or double-sided tapes are used to position the display panel 3 and the cable 6 in the casing 2 in the notebook computer in the comparative technique shown in FIG. 5A and FIG. 5B, it is possible to position the display panel 3 using only the four fixtures 5 disposed at the four corners in the embodiment. For this reason, it is then possible to reduce the number of parts. Furthermore, since the fixture 5 can also be installed by fitting the protruding portion 54 and the wall portion 52 to the rib 4, it is unnecessary to perform detailed work such as adhering the sponges 62 to the rib 61 as in the notebook computer in the comparative technique.

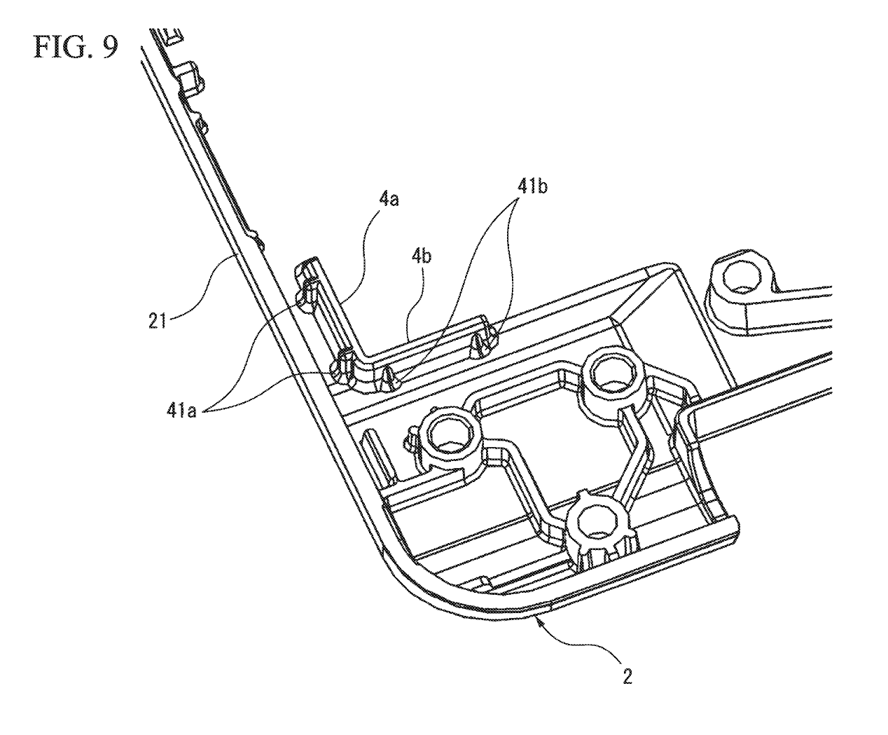

FIG. 9 is a perspective view showing a shape of the rib 4 formed in the casing 2. The rib 4 is formed to have an L shape in a planar view to correspond to the four corners of the display panel to position the display panel 3. That is to say, the rib 4 is formed as continuous bodies such as ribs 4a and 4b to face the orthogonal side surfaces 31 and 33 of a corner of the display panel 3. Furthermore, a pair of projecting portions 41a and 41b provided in accordance with widths of the protruding portions 54a and 54b are provided to facilitate the fitting of the protruding portions 54a and 54b in the fixture 5 shown in FIG. 7A and FIG. 7B. The positioning of the fixture 5 is facilitated by forming the projecting portions 41a and 41b.

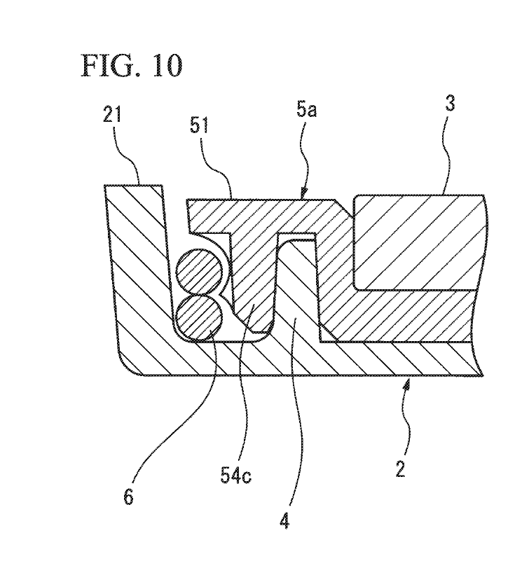

Also, a length L1 (refer to FIG. 6) of the flange portion 51 extending in an edge direction from the wall portion 52 of the fixture 5 is determined by a length L0 between the edge portion 21 of the casing 2 and the rib 4. The length L1 may be provided to be substantially equal to a length in which the flange portion 51 is in contact with the edge portion 21, that is, L0. Furthermore, as shown in FIG. 6, for example, when a distance between the edge portion 21 and a distal end of the flange portion 51 is a distance smaller than a diameter of the cable 6, the length L1 of the flange portion 51 may be formed to be shorter than the length L0 between the edge portion 21 of the casing 2 and the rib 4. In addition, as in the protruding portion 54c in the fixture 5a shown in FIG. 10, a cross-sectional shape of an outer side of the protruding portion 54c is formed to have a corrugated shape corresponding to a cross-sectional shape of the cable 6 so that a position of the cable 6 is prevented from deviating when installing the fixture 5a. It should be noted that, although the notebook computer is shown as an example of the information processing device in the embodiment, the information processing device may be any device having a display panel used therein, for example, a smartphone, a mobile phone, a tablet, and the like.

The present invention has been described in detail above with reference to the preferred embodiments thereof.

What is claimed is:

1. An information processing device comprising:
a display panel;
a casing having the display panel enclosed therein;
a rib provided at a predetermined interval from an edge of the casing and configured to position the display panel; and
a fixture provided between the display panel and the rib,
wherein the fixture includes a flange portion extending in a direction toward the edge of the casing from the fixture and configured to block the movement of a cable wired between an edge of the casing and the rib.

2. The information processing device according to claim 1, wherein the fixture further includes a wall portion which is in contact with the rib on one surface thereof and is in contact with a part of a side surface of the display panel on the other surface opposite to the one surface and a protruding portion protruding from the flange portion and configured to sandwich the rib between the protruding portion and the wall portion.

3. A fixture which is installed between a display panel and a rib in a casing and positions the display panel, comprising:
a wall portion which is in contact with a part of a side surface of the display panel on one surface thereof and is in contact with the rib on the other surface opposite to the one surface;
a receiving portion extending from one end portion of the wall portion to receive a rear surface of the display panel; and
a flange portion extending from the other end portion of the wall portion toward a side opposite to the receiving portion.

4. The fixture according to claim 3, further comprising:
a protruding portion protruding from the flange portion and configured to sandwich the rib between the protruding portion and the wall portion.

5. The fixture according to claim 4, wherein a cross section on outer side of the protruding portion is formed a wave shape according to an external form of a cable.
